(19) United States
(12) Patent Application Publication
(10) Pub. No.: US 2026/0050028 A1
(43) Pub. Date: Feb. 19, 2026

(54) LOOP GAIN MEASUREMENT PROBE AND MEASUREMENT SYSTEM

(71) Applicant: Rohde & Schwarz GmbH & Co. KG, Muenchen (DE)

(72) Inventor: Christoph Hammerl, Muenchen (DE)

(21) Appl. No.: 18/805,360

(22) Filed: Aug. 14, 2024

(51) Int. Cl. G01R 31/28

(52) U.S. Cl. CPC G01R 31/2884

(57) ABSTRACT

Embodiments of the present disclosure relate to a loop gain measurement probe including a printed circuit board and an injection transformer. The loop gain measurement probe includes a first connection interface and a second connection interface, which are connected with the injection transformer and are connectable with a device under test. The loop gain measurement probe includes a first output and a second output, which are connectable to the test and/or measurement instrument. The loop gain measurement probe includes an input connected with the injection transformer and capable of forwarding an input signal received to the injection transformer. The loop gain measurement probe includes a first passive probe circuit and a second passive probe circuit, which are connected with the first connection interface and the first output as well as with the second connection interface and the second output, respectively.

### FIELD OF THE DISCLOSURE

Embodiments of the present disclosure relate to a loop gain measurement probe. Further, embodiments of the present disclosure also relate to a measurement system.

### BACKGROUND

In the state of the art, measurement systems are known that are used to measure a loop gain of a device under test, particularly a device under test having a feedback circuit, for instance a voltage regulator.

The measurement systems known in the state of the art are based on several separately formed devices that are interconnected with each other, for instance a test and/or measurement instrument that is connected to an injection transformer which performs a voltage injection on the device under test. In addition, separately formed probes are used for probing the device under test. Consequently, the device under test has to be contacted via four different contacts. Therefore, these kinds of measurement systems are complex with regard to their general setup, particularly due to the number of contacts required for testing. Moreover, it is complicated to measure devices under test at locations which are not easy to access due to the space required by the components of the measurement system. Specifically, the measurement systems are not suitable for probing integrated circuits that are typically very small.

Accordingly, there is a need for a possibility to measure a wide range of devices under test with regard to their loop gain, particularly the loop gain of integrated circuits

### SUMMARY

The following summary of the present disclosure is intended to introduce different concepts in a simplified form that are described in further detail in the detailed description provided below. This summary is neither intended to denote essential features of the present disclosure nor shall this summary be used as an aid in determining the scope of the claimed subject matter.

Embodiments of the present disclosure provide a loop gain measurement probe for being connected to a test and/or measurement instrument. In an embodiment, the loop gain measurement probe comprises a printed circuit board on which an injection transformer is arranged. The loop gain measurement probe comprises a first connection interface as well as a second connection interface, wherein both connection interfaces are connected with the injection transformer and are connectable with a device under test (DUT). The loop gain measurement probe also comprises a first output as well as a second output, wherein the outputs are connectable to the test and/or measurement instrument. The loop gain measurement probe further comprises an input connected with the injection transformer and capable of forwarding an input signal received from the test and/or measurement instrument to the injection transformer. The loop gain measurement probe also comprises a first passive probe circuit and a second passive probe circuit. The first passive probe circuit is connected with the first connection interface and the first output, whereas the second passive probe circuit is connected with the second connection interface and the second output.

Embodiments of the present disclosure also relate to a loop gain measurement probe for being connected with a test and/or measurement instrument. In an embodiment, the loop gain measurement probe comprises a printed circuit board on which an injection transformer is arranged. The loop gain measurement probe also comprises a first connection interface as well as a second connection interface. The connection interfaces are connected with the injection transformer and are connectable with the device under test, DUT. The loop gain measurement probe also comprises a first output as well as a second output, which are arranged on the printed circuit board and connectable to the test and/or measurement instrument. The loop gain measurement probe further comprises an input that is connected with the injection transformer and capable of forwarding an input signal received from the test and/or measurement instrument to the injection transformer. The input is also arranged on the printed circuit board.

Embodiments of the present disclosure further provide a measurement system for performing a loop gain measurement of a device under test. In an embodiment, the measurement system comprises a test and/or measurement instrument and a loop gain measurement probe. The loop gain measurement probe comprises a printed circuit board, an injection transformer arranged on the printed circuit board, a first connection interface connected with the injection transformer and connectable to the device under test, a second connection interface connected with the injection transformer and connectable to the device under test, a first output connected with the first connection interface via a first passive probe circuit, a second output connected with a second connection interface via a second passive probe circuit, and an input connected with the injection transformer. The test and/or measurement instrument is connected with the first output, the second output and the input of the loop gain measurement probe. The test and/or measurement instrument forwards an input signal to the loop gain measurement probe, which is received by the input of the loop gain measurement probe and internally forwarded to the injection transformer of the loop gain measurement probe.

Accordingly, the present disclosure provides examples of a single device, namely the loop gain measurement probe, which is interconnected between the device under test and the test and/or measurement instrument for performing the loop gain measurements on the device under test. Therefore, it is not necessary to provide several different separately formed components to be interconnected with each other for establishing the respective setup, thereby reducing the overall efforts required for performing the loop gain measurements on the device under test.

In addition, these examples of the loop gain measurement probe form a compact device that can be used for testing small devices under test which cannot be tested by measurement systems known in the state of the art, for instance integrated circuits.

The loop gain measurement probe according to embodiments of the present disclosure provide a printed circuit board on which all components required for performing the measurements are provided, namely the input, the outputs, the injection transformer, the passive probe circuits as well as the connection interfaces.

In an embodiment, the overall number of required contacts with the device under test can be reduced significantly, as only two connection interfaces for the device under test are required rather than four contacts that were necessary in the state of the art. This also ensures simplified probing of small devices under test such as integrated circuits.

Generally, the injection transformer emulates a galvanically isolated alternating current (AC) voltage source, as the injection transformer is connected with the two connection interfaces via which the device under test is connected as well as the input for receiving the input signal from the test and/or measurement instrument.

As indicated above, the two connection interfaces are connected with the passive probe circuits simultaneously which in turn are connected with the outputs to which the test and/or measurement instrument is connected.

The loop gain measurement probe according to some embodiments of the present disclosure has five interfaces in total, specifically two interfaces for being connected to the device under test, namely the connection interfaces, as well as three interfaces for being connected to the test and/or measurement instrument, namely the input and the outputs.

In embodiments, the passive probe circuits are provided which are arranged on the printed circuit board, thereby providing integrated passive probe circuits.

An aspect provides that the test and/or measurement instrument is, for example, an oscilloscope. Therefore, the oscilloscope may comprise input interfaces for being connected with the outputs of the loop gain measurement probe as well as at least one output interface to which the input of the loop gain measurement probe is connected, for instance a signal generator output interface. Accordingly, the oscilloscope may comprise an integrated signal generator that is capable of generating the input signal that is forwarded to the input of the loop gain measurement probe. As indicated above, the input signal received from the test and/or measurement instrument is forwarded to the device under test via the injection transformer and the connection interfaces that are connected with the injection transformer.

A further aspect provides that both the first output and the second output are, for example, arranged on the printed circuit board. Thus, a compact and integrally formed loop gain measurement probe can be achieved, which may be used for performing loop gain measurements on small devices under test like integrated circuits.

In a similar manner, both the first connection interface and the second connection interface may be, for example, arranged on the printed circuit board at least partly. In an embodiment, the connection interfaces may be established by wires that are connected with the printed circuit board via ends, whereas the opposite ends are used for probing the device under test. Hence, the loop gain measurement probe can be realized in a compact and integrated manner.

In addition, the input may also be arranged on the printed circuit board. A compact design of the loop gain measurement probe is obtained. In an embodiment, all interfaces of the loop gain measurement probe, namely the input, the outputs and the connection interfaces, may be provided on the printed circuit board.

In an embodiment, the injection transformer may provide a galvanic isolation between the input and the first connection interface as well as the second connection interface. Accordingly, the injection transformer is capable of galvanically isolating a signal source connected with the input from the connection interfaces as well as the outputs, as the outputs are connected to the connection interfaces via the passive probe circuits accordingly.

According to an example, the injection transformer comprises a ferrite core. The ferrite core provides high magnetic permeability coupled with low electrical conductivity, thereby preventing eddy currents. In addition, ferrite cores have comparatively low losses at high frequencies. Moreover, examples of the injection transformer comprise windings wound around the ferrite core.

In an embodiment, the injection transformer may comprise windings, wherein the windings comprise a twisted pair wire. The twisted pair wire relates to two conductors of a single circuit, which are twisted. Therefore, the twisted pair wire improves the electromagnetic compatibility, as the twisted pair wire reduces electromagnetic radiation from the pair and crosstalk between neighboring pairs while simultaneously improving rejection of external electromagnetic interference.

In an embodiment, the loop gain measurement probe comprises a first capacitor that is arranged in parallel to the first passive probe. The first capacitor is also referred to as a compensation capacitor. The first capacitor may be used in case of certain signals like rectangular signals or square wave signals, as the capacitor acts as a high-pass filter.

In an embodiment, the loop gain measurement probe may also comprise a second capacitor that is connected in parallel to the second passive probe circuit. As indicated above, the second capacitor may also be used in case of certain signals like rectangular signals or square wave signals, as the capacitor acts as a high-pass filter.

In an embodiment, the loop gain measurement probe may comprise an injection resistor that is arranged between the first connection interface and the second connection interface. The injection resistor may have a resistance of, for example, 20 Ohms.

In an embodiment, the printed circuit board may comprise at least one ground connection. This ensures that the printed circuit board is grounded, thereby improving the measurement accuracy.

In an embodiment, the injection transformer may comprise at least one ground connection. Thus, a grounding of the injection transformer can be ensured as well.

According to a further aspect, both the first output and the second output are, for example, coaxial connectors. Therefore, the loop gain measurement probe can be easily connected with the test and/or measurement instrument by coaxial cables which are typically used for connecting a test and/or measurement instrument with additional devices, especially the loop gain measurement probe according to the present disclosure.

A further aspect provides that both the first connection interface and the second connection interface are provided by, for example, solderable wires. These wires are connected with ends to a circuit on the printed circuit board, whereas opposite ends of the solderable wires can be connected to the device under test. Hence, the solderable wires ensure that the loop gain measurement probe can be connected via its connection interfaces with different kinds of devices under test in a simplified manner. In an embodiment, the wires are flexible, thereby ensuring that regions of the device under test can be probed which are hard to reach by means of separately formed probes.

According to a further aspect, both the first connection interface and the second connection interface, for example, are provided by at least one pin header. The pin header also ensures that different kinds of devices under test can be used for performing the loop gain measurements in a simplified manner. In an embodiment, devices under test can be contacted by pins of the pin header.

In an embodiment, the loop gain measurement probe may comprise a housing that encompasses the printed circuit board. At least the first connection interface and the second connection interface, the input as well as the first output and the second output all located at outer sides of the housing. The respective outputs and connection interfaces may be located at different outer sides of the housing, for instance opposite outer sides. In general, the connectability of the loop gain measurement probe can be simplified by locating the input as well as the outputs on the same outer side, as the input and the outputs are connected with the test and/or measurement instrument, whereas the connection interfaces are used for being connected to the device under test.

In an embodiment, the housing may have at least one recess through which the printed circuit board may partly pass through, for instance a portion of the printed circuit board, on which the connection interfaces are provided

### DESCRIPTION OF THE DRAWINGS

The foregoing aspects and many of the attending advantages of the claimed subject matter will become more readily appreciated as the same become better understood by reference to the following description, when taken in conjunction with the accompanying drawings, wherein:

FIG. 1 schematically shows an overview of a measurement system according to an embodiment of the present disclosure, which comprises a loop gain measurement probe according to an embodiment of the present disclosure;

FIG. 2 shows an overview of a loop gain measurement probe according to an embodiment of the present disclosure; and

FIG. 3 shows the loop gain measurement probe of FIG. 2 without a housing.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

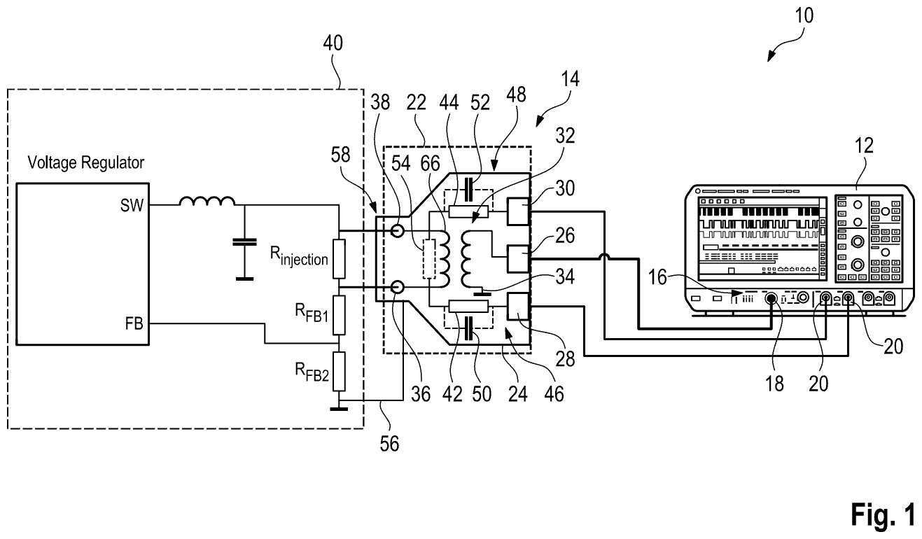

In FIG. 1, an example of a measurement system 10 is shown that comprises a test and/or measurement instrument 12, for instance an oscilloscope, as well as a loop gain measurement probe 14. As shown in the example embodiment of FIG. 1, the test and/or measurement instrument 12 comprises an internal signal generator 16 that is connected with an output interface 18 of the test and/or measurement instrument 12. In addition, the test and/or measurement instrument 12 comprises at least two input interfaces 20 that are connected with the loop gain measurement probe 14.

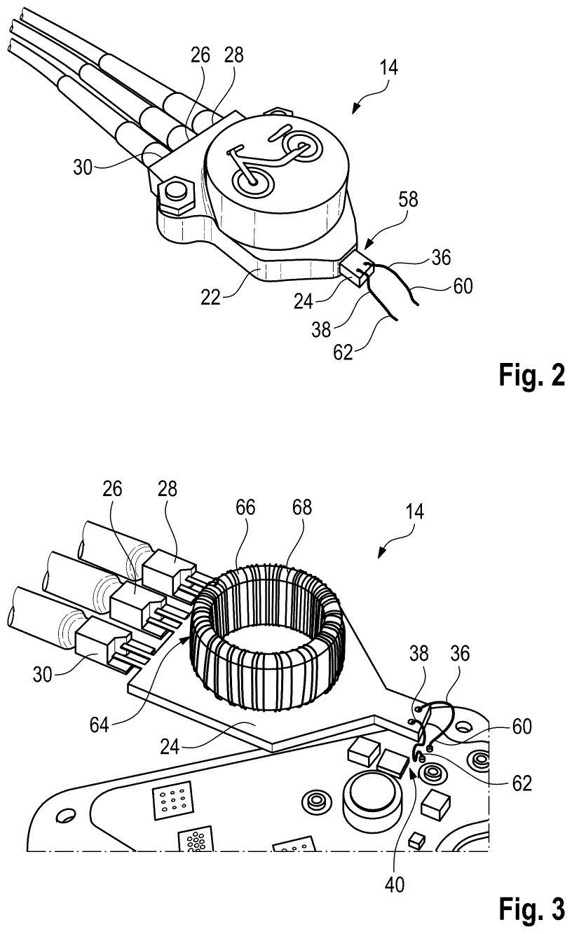

The loop gain measurement probe 14, which is shown in FIG. 2 in detail, has a housing 22 that encompasses a printed circuit board 24. On the printed circuit board 24, an input 26 is arranged that is connected with the output interface 18 of the test and/or measurement instrument 12. In addition, a first output 28 as well as a second output 30 are arranged on the printed circuit board 24 as well, which are connected with the input interfaces 18 of the test and/or measurement instrument 12.

Generally, the outputs 28, 30 and, optionally, the input 26 may be established by coaxial connectors such that the loop gain measurement probe 14 can be connected to the test and/or measurement instrument 12 via coaxial cables.

Referring back to FIG. 1, the loop and measurement probe 14 further comprises an injection transformer 32 that is also arranged on the printed circuit board 24 and connected with the input 26. The injection transformer 32 provides a galvanic isolation of the input 26 with respect to other components arranged on the printed circuit board 24. In an embodiment, the injection transformer 32 has a ground connection 34 such that the injection transformer 32 is grounded, namely on the side associated with the test and/or measurement instrument 12.

In the embodiment of FIG. 1, the injection transformer 32 is connected with a first connection interface 36 as well as a second connection interface 38 which are used for being connected to a device under test 40 on which loop gain measurements are performed by the measurement system 10.

As shown in FIG. 1, the first connection interface 36 as well as the second connection interface 38 are also connected to the first output 28 and the second output 30, respectively. In an embodiment, the first connection interface 36 is connected with the first output 28 via a first passive probe circuit 42, whereas the second connection interface 38 is connected with the second output 30 via a second passive probe circuit 44. In an embodiment, the first passive probe circuit 42 as well as the second passive probe circuit 44 are also arranged on the printed circuit board 24 such that the passive probe circuits 42, 44 are integrated passive probes.

Accordingly, the loop gain measurement probe 14 has a first branch 46 that is provided between the first connection interface 36 and the first output 28, wherein the first passive probe circuit 42 is located in the first branch 46. Moreover, the loop gain measurement probe 14 has a second branch 48 that is provided between the second connection interface 38 and the second output 30, wherein the second passive probe circuit 44 is located in the second branch 48.

In an embodiment, a first capacitor 50 may be arranged in the first branch 46, namely in parallel to the first passive probe circuit 42, whereas a second capacitor 52 may be arranged in the second branch 48, namely in parallel to the second passive probe circuit 44. The capacitors 50, 52 are optional and typically used in case rectangular signals are used for performing the loop gain measurements. As shown in FIG. 1, an optional injection resistor 54 may be arranged between the connection interfaces 36, 38. The printed circuit board 26 may also have an optional ground connection 56.

As shown in FIG. 2, the connection interfaces 36, 38, the input 26 as well as the outputs 28, 30 may be arranged on outer sides of the housing 22. Specifically, the input 26 as well as the outputs 28, 30, which are to be connected with the test and/or measurement instrument 12, are located on a common outer side, whereas the connection interfaces 36, 38 are commonly located on a different outer side of the housing 22, for example an opposite outer side. However, the housing 22 may also have a recess 58 through which a portion of the printed circuit board 24 passes, thereby ensuring better accessibility of the connection interfaces 36, 38. In the shown embodiment, the connection interfaces 36, 38 are realized by solderable wires 60, 62 which are soldered to the printed circuit board 24, thereby being arranged on the printed circuit board 24 at least partly. Alternatively, the connection interfaces 36, 38 may be realized by a pin header having several pins, e.g. at least two pins.

An example embodiment of the loop gain measurement probe 14 is shown in FIG. 3 in more detail, e.g. without housing 22. Accordingly, the injection transformer 32 is visible, which comprises a ferrite core 64 around which several windings 66 are wound, for example a twisted pair wire 68.

In general, the test and/or measurement instrument 12 generates via its signal generator 16 an input signal that is forwarded to the input 26 of the loop gain measurement probe 14 via the output interface 18 of the test and/or measurement instrument 12.

The input signal received via the input 26 is forwarded via the injection transformer 32 to both connection interfaces 36, 38. Hence, the injection transformer 32 is acting as an alternating current (AC) source with regard to the connection interfaces 36, 38 via which the device under test 40 is probed by the loop gain measurement probe 14.

The signals provided at the connection interfaces 36, 38 are forwarded to the device under test 40 for measuring a loop gain of the device under test 40. A respective response signal of the device under test 40 is probed via the connection interfaces 36, 38 as well, which is processed by the passive probe circuits 42, 44 connected with the connection interfaces 36, 38 as indicated above. The signals processed by the passive probes circuits 42, 44 are then outputted via the outputs 28, 30, respectively. The outputs 28, 30 of the loop gain measurement probe 14 are connected with the input interfaces 20 of the test and/or measurement instrument 12 such that the outputted signals, namely the signals probed and processed by the passive probes circuits 42, 44, are analyzed by the test and/or measurement instrument 12.

Accordingly, loop gain measurements can be performed on the device under test 40 in a simplified and easy manner, as the loop gain measurement probe 14 can be used that is interconnected between the test and/or measurement instrument 12 and the device under test 40. Due to its compact design and the reduced number of contacts required for performing the loop gain measurements, the loop gain measurement probe 14 as well as the measurement system 10 may be used for performing the loop gain measurement on an integrated circuit, IC.

Certain embodiments disclosed herein include systems, apparatus, modules, units, devices, components, etc., that utilize circuitry (e.g., one or more circuits) in order to implement standards, protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be used synonymously with the term “signals” in this paragraph. It will be further appreciated that the terms “circuitry,” “circuit,” “one or more circuits,” etc., can be used synonymously herein.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure.

In the detailed description herein, references to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. In addition, when a particular feature, structure, or characteristic is described in connection with an embodiment, it is submitted that it is within the knowledge of one skilled in the art to affect such feature, structure, or characteristic in connection with other embodiments whether or not explicitly described. After reading the description, it will be apparent to one skilled in the relevant art(s) how to implement the disclosure in alternative embodiments. Thus, it will be appreciated that embodiments of the present disclosure may employ any combination of features described herein. All such combinations or sub-combinations of features are within the scope of the present disclosure.

Throughout this specification, terms of art may be used. These terms are to take on their ordinary meaning in the art from which they come, unless specifically defined herein or the context of their use would clearly suggest otherwise.

The drawings in the FIGURES are not to scale. Similar elements are generally denoted by similar references in the FIGURES. For the purposes of this disclosure, the same or similar elements may bear the same references. Furthermore, the presence of reference numbers or letters in the drawings cannot be considered limiting, even when such numbers or letters are indicated in the claims.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. A loop gain measurement probe, comprising:
a printed circuit board;
an injection transformer that is arranged on the printed circuit board;
a first connection interface and a second connection interface, wherein the first connection interface is connected with the injection transformer and are connectable with a device under test (DUT), and wherein the second connection interface is also connected with the injection transformer and connectable with the device under test (DUT);
a first output connectable to a test and/or measurement instrument and a second output connectable to the test and/or measurement instrument;
an input connected with the injection transformer and capable of forwarding an input signal received to the injection transformer;
a first passive probe circuit and a second passive probe circuit, wherein the first passive probe circuit is connected with the first connection interface and the first output, and wherein the second passive probe circuit is connected with the second connection interface and the second output.

2. The loop gain measurement probe according to claim 1, wherein both the first output and the second output are arranged on the printed circuit board.

3. The loop gain measurement probe according to claim 1, wherein both the first connection interface and the second connection interface are arranged on the printed circuit board at least partly.

4. The loop gain measurement probe according to claim 1, wherein the input is arranged on the printed circuit board.

5. The loop gain measurement probe according to claim 1, wherein the injection transformer provides a galvanic isolation between the input and the first connection interface and the second connection interface.

6. The loop gain measurement probe according to claim 1, wherein the injection transformer comprises a ferrite core.

7. The loop gain measurement probe according to claim 1, wherein the injection transformer comprises windings, and wherein the windings comprise a twisted pair wire.

8. The loop gain measurement probe according to claim 1, further comprising a first capacitor that is connected in parallel to the first passive probe circuit.

9. The loop gain measurement probe according to claim 1, further comprising a second capacitor that is connected in parallel to the second passive probe circuit.

10. The loop gain measurement probe according to claim 1, further comprising an injection resistor that is arranged between the first connection interface and the second connection interface.

11. The loop gain measurement probe according to claim 1, wherein the printed circuit board comprises at least one ground connection.

12. The loop gain measurement probe according to claim 1, wherein the injection transformer comprises at least one ground connection.

13. The loop gain measurement probe according to claim 1, wherein both the first output and the second output are coaxial connectors.

14. The loop gain measurement probe according to claim 1, wherein both the first connection interface and the second connection interface are provided by solderable wires.

15. The loop gain measurement probe according to claim 1, wherein both the first connection interface and the second connection interface are provided by at least one pin header.

16. The loop gain measurement probe according to claim 1, further comprising a housing that encompasses the printed circuit board, and wherein at least the first connection interface and the second connection interface, the input as well as the first output and the second output are located at outer sides of the housing.

17. A loop gain measurement probe, comprising:
a printed circuit board;
an injection transformer that is arranged on the printed circuit board;
a first connection interface and a second connection interface, wherein the first connection interface is connected with the injection transformer and is connectable with a device under test (DUT), and wherein the second connection interface is also connected with the injection transformer and is connectable with the device under test (DUT);
a first output arranged on the printed circuit board and connectable to a test and/or measurement instrument;
a second output arranged on the printed circuit board and connectable to the test and/or measurement instrument;
an input arranged on the printed circuit board and connected with the injection transformer,
wherein the input is capable of forwarding an input signal received from the test and/or measurement instrument to the injection transformer.

18. A measurement system for performing a loop gain measurement of a device under test, wherein the measurement system comprises a test and/or measurement instrument and a loop gain measurement probe,
wherein the loop gain measurement probe comprises:
a printed circuit board;
an injection transformer arranged on the printed circuit board;
a first connection interface connected with the injection transformer and connectable to the device under test;
a second connection interface connected with the injection transformer and connectable to the device under test;
a first output connected with the first connection interface via a first passive probe circuit;
a second output connected with the second connection interface via a second passive probe circuit; and
an input connected with the injection transformer,
wherein the test and/or measurement instrument is connected with the first output, the second output and the input of the loop gain measurement probe,
wherein the test and/or measurement instrument forwards an input signal to the loop gain measurement probe, which is received by the input of the loop gain measurement probe and internally forwarded to the injection transformer of the loop gain measurement probe.

19. The measurement system according to claim 18, wherein the test and/or measurement instrument is an oscilloscope.
